(19) United States
(12) Patent Application Publication
(10) Pub. No.: US 2004/0261832 A1
(43) Pub. Date: Dec. 30, 2004

(54) Method and apparatus for measuring photoelectric conversion characteristics of solar cell element

(75) Inventors: Shunichi Haga, Nara (JP); Jinsho Matsuyama, Kyoto (JP); Satoshi Shinkura, Nara (JP)

Correspondence Address: FITZPATRICK CELLA HARPER & SCINTO, 30 ROCKEFELLER PLAZA, NEW YORK, NY, 10112, US

(73) Assignee: Canon Kabushiki Kaisha, Tokyo (JP)

(21) Appl. No.: 10/864,475

(22) Filed: Jun. 10, 2004

(30) Foreign Application Priority Data
Jun. 16, 2003 (JP) 2003-170419

(51) Int. Cl. H01L 35/00; H01L 31/00; H01L 37/00

(52) U.S. Cl. 136/206; 136/252

(57) ABSTRACT

A method of measuring the photoelectric conversion characteristics of a solar cell element is provided which comprises the steps of placing and fixing a solar cell element on a stage with a light-receiving surface of the solar cell element being an upper surface, irradiating a photoelectric conversion layer of the solar cell element with a light from the upper surface side, and bringing probes provided on a side opposite to the light-receiving surface side into contact with a first electrode portion and a protruding electrode portion of a second electrode, respectively. An apparatus for measuring the photoelectric conversion characteristics of a solar cell element is also provided.

### BACKGROUND OF THE INVENTION

1. Field of the Invention

The present invention relates to a measurement method and a measurement apparatus for measuring photoelectric conversion characteristics by irradiating a solar cell element with a light, which are for actualizing the improvement of the measurement accuracy of the photoelectric conversion characteristics.

2. Related Background Art

In these years, the demand has been increasing for the solar energy generation based on the solar cell element that utilizes solar radiation, as the clean and safe energy free from the global warming issue due to carbon dioxide and free from the concern for the radioactive contamination due to nuclear power generation.

Under these circumstances, various research and development are being promoted towards practical application of various solar cells. Among the various solar cell elements, the amorphous silicon solar cell is one of the solar cell elements that attract attention from the advantage that formation of large area cells is easy and operation with a thin film is possible.

Additionally, in the research and development of the above described solar cells, development of the technology for measuring the various characteristics of the solar cell element is an important development theme from the viewpoints of grasping the technical problems in the development of the manufacture technology of the solar cell element and detecting at early stages the problems on the production management toward practical application, and moreover, from the viewpoint of an effective means for sorting defective products; among others, the development of the measurement technology of the photoelectric conversion characteristic (I-V characteristic) is a crucial point for developing the solar cell having good characteristics and for carrying out accurate detection and sorting of defective products.

Conventionally, as the method for accurately measuring the photoelectric conversion characteristics of a thin film solar cell element including an amorphous silicon solar cell, a method for measuring the characteristics by use of a light source (solar simulator) has been commonly employed. For characteristic measurement, a method is commonly adopted in which characteristics are measured, while a solar cell element is being irradiated with a light from a light source, by connecting thin-film-shaped take-out electrodes arranged on the solar cell element to the measurement apparatus by means of a contact device (probes or the like) for measurement.

Usually, the electrode of a solar cell element is such that electrodes are generally arranged on both sides, and a single element falls short of output power, so that a plurality of elements are required to be assembled in series. In response to this requirement, some solar cell elements have electrode shapes in which the electrodes protrude from the contour of the element.

Now, description will be made below with reference to the accompanying drawings. FIG. 10 is a plan view of a conventional solar cell element as viewed from the side of the light-receiving surface thereof, including a partial perspective view. FIG. 11 is a sectional view showing the outline structure of a conventional solar cell element. FIG. 12 is a schematic view illustrating the probe contact scheme in a conventional method and a conventional apparatus for measuring the photoelectric conversion characteristics of a solar cell element.

In FIGS. 10, 11 and 12, reference numeral 1 denotes a solar cell element, 2 denotes a light-receiving surface of the solar cell element 1, 201 denotes a photoelectric conversion layer of the solar cell element 1, 3 denotes a substrate on which the photoelectric conversion layer 201 is formed, 301 denotes an upper electrode of the photoelectric conversion layer 201, 302 denotes a lower electrode arranged on the substrate 3 side of the photoelectric conversion layer 201, 4 denotes a second electrode electrically connected to the upper electrode 301 and arranged on the light-receiving surface 2 side, 401 denotes an electrode portion which is a part of the second electrode 4 and protrudes from the substrate 3, 5 denotes a first electrode portion electrically connected to the lower electrode 302 and arranged on a lower surface of the substrate 3, 6 denotes a stage on which the solar cell element 1 is mounted, 7 denotes a driver for raising/lowering the stage 6, 801 and 802 denote probes to be in contact with the second electrode 4 and the first electrode portion 5, respectively, 901 and 902 denotes blocks for fixing the probes 801 and 802, 1001 and 1002 denotes drivers for the probes 801 and 802 and for the probe fixing blocks 901 and 902, respectively, 11 denotes a light shielding mask, 12 denotes an aperture of the light shielding mask 11, 13 denotes a gap between the lower surface of the light shielding mask 11 and the upper surface of the second electrode 4, and 14 denotes a light for irradiating the light-receiving surface 2 of the solar cell element 1 therewith.

First of all, description will be made on the structure of a solar cell element generally manufactured. As shown in FIGS. 10 and 11, a general solar cell element 1 is constituted of a photoelectric conversion layer 201 in which a pn junction or a pin junction is formed, an upper electrode 301 formed on a light-receiving surface 2, and a lower electrode 302 formed on the opposite surface of the light-receiving surface 2, and generally, these electrode are respectively connected to a second electrode 4 and a first electrode portion 5.

Next, description will be made on the conventional method for measuring the photoelectric conversion characteristics of a solar cell element generally manufactured. As the method for measuring the photoelectric conversion characteristics of the solar cell element 1 having a structure as described above, there is generally employed a method in which the light-receiving surface 2 is arranged as the upper surface, the contact to the second electrode 4 is made from the upper surface side with the aid of a probe 801 arranged above the second electrode 4, the contact to the first electrode portion 5 is made from the lower surface side with the aid of a probe 802 arranged below the first electrode portion 5, the solar cell element is irradiated with the light 14 from the upper surface side, and thus the photoelectric conversion characteristics are measured.

Supplementary description will be made below in a more specific manner. As shown in FIG. 12, the solar cell element 1 is mounted on the stage 6 with the light-receiving surface 2 thereof being the upper surface and is fixed in close contact manner with the lower surface of the substrate 3 of the solar cell element 1 being in contact with the stage 6, then the stage 6 is raised by means of the driver 7 for raising/lowering, drivers 1001 and 1002 for raising/lowering are operated respectively for the probe 801 arranged above the light-receiving surface 2 of the solar cell element 1 and the probe 802 arranged on the side of the surface opposite thereto, the probes 801 and 802 are brought into contact respectively with the second electrode 4 and the first electrode portion 5 of the solar cell element 1, the light-receiving surface 2 is irradiated with the light 14 through the aperture 12 of the light shielding mask 11, and thus the photoelectric conversion characteristics are measured.

Japanese Patent Application Laid-Open No. H11-26785 discloses a method for measuring the photoelectric conversion characteristics by partially irradiating a light-receiving surface of a solar cell element with a light from a light source by means of a light shielding mask or the like. According to this method, the distance between the light-receiving surface and the probe can be made sufficiently large. In other words, there is a sufficient space for arranging and fixing the probes on the light-receiving surface side, so that for the second electrode 4, a method can be applied in which as shown in FIG. 12, the probes are provided on the light-receiving surface side and brought into contact with the second electrode to effect the measurement.

However, according to the method described in Japanese Patent Application Laid-Open No. H11-26785, the whole surface measurement of the light-receiving surface requires repeating fractional surface measurement as a result of the partial irradiation, so that the method is not satisfactory from the viewpoints of measurement time and accuracy.

On the other hand, when the whole light-receiving surface of a solar cell element is irradiated with a light and the photoelectric conversion characteristics are measured by means of the above described conventional probe contact scheme, the distance between the light-receiving surface and the probe cannot be made sufficiently large. Consequently, there has been posed a problem that the probe disposed on the light-receiving surface side is also irradiated with the light from the light source, whereby the irradiation light is reflected from and scattered on the surface of the probe, thus affecting the photoelectric conversion characteristics. Additionally, there has occurred a problem that even when the surface of the probe is subjected to the antireflection treatment, the probe and the raising/lowering mechanism for the contact of the probe with the electrode disturb the light irradiation conditions, thereby affecting the measurement of the photoelectric conversion characteristics.

### SUMMARY OF THE INVENTION

The present invention, in view of the above described problems, takes as its object the provision of a method and an apparatus for measuring the photoelectric conversion characteristics of a solar cell element in which method and apparatus the measurement accuracy of the photoelectric conversion characteristics of a solar cell element is improved by attaining stable contact free from the affections to the light irradiated to the light-receiving surface by the probe and the driving system for contact of the probe with the electrode.

For the purpose of solving the above-described problems, according to a first aspect of the present invention, there is provided a method of measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light, the method comprising the steps of:

fixing the solar cell element with a light-receiving-side surface thereof having the photoelectric conversion layer being an upper surface; irradiating the photoelectric conversion layer of the solar cell element with a light from the upper surface side; and bringing probes provided on the substrate side of the solar cell element into contact with the first electrode portion and the protruding second electrode portion.

According to the first aspect of the present invention, since all the probes are disposed on the substrate side, namely, on the side opposite to the light-receiving surface side of the element, there is no problem that the light irradiation conditions are disturbed in the measurement of the photoelectric conversion characteristics of the solar cell element, whereby the measurement accuracy can be improved.

For the purpose of solving the above-described problems, according to a second aspect of the present invention, there is provided a method of measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the method comprising the steps of:

fixing the solar cell element with a light-receiving-side surface thereof having the photoelectric conversion layer being an upper surface; irradiating the photoelectric conversion layer of the solar cell element with a light from the upper surface side; bringing a probe provided on the substrate side of the solar cell element into contact with the first electrode portion; and bringing into contact with the second protruding electrode portion, a plate-shaped probe disposed and fixed with no clearance between the protruding second electrode portion and a lower surface of the light shielding mask.

According to the second aspect of the present invention, since the probe brought into contact with the second electrode portion on the light-receiving surface side is disposed below the lower surface of the light shielding mask without clearance, there is no problem that the light irradiation conditions are disturbed in the measurement of the photoelectric conversion characteristics of the solar cell element, whereby the measurement accuracy can be improved.

For the purpose of solving the above-described problems, according to a third aspect of the present invention, there is provided a method of measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the method comprising the steps of:

irradiating the photoelectric conversion layer of the solar cell element with a light from the upper surface side; placing and fixing on a stage the solar cell element with a light-receiving-side surface thereof having the photoelectric conversion layer being the upper surface; pressing the solar cell element placed and fixed on the stage against the lower surface of the light shielding mask disposed and fixed on the side of the upper surface as the light-receiving surface of the solar cell element, through a raising/lowering movement of the stage, and then fixing the solar cell element; and bringing probes provided on the substrate side of the solar cell element into contact with the first electrode portion and the protruding second electrode portion, respectively.

According to the third aspect of the present invention, since all the probes are arranged on the substrate side, namely, on the side opposite to the side of the light-receiving surface of the element, there is no problem that the light irradiation conditions are disturbed in the measurement of the photoelectric conversion characteristics of the solar cell element, whereby the measurement accuracy can be improved.

For the purpose of solving the above-described problems, according to a fourth aspect of the present invention, there is provided an apparatus for measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light, the apparatus comprising:

means for fixing and holding the solar cell element with a light-receiving-side surface of the solar cell element having the photoelectric conversion layer being an upper surface;

a light source for irradiating the photoelectric conversion layer of the solar cell element with a light; and

a probe raising/lowering drive mechanism for bringing probes provided on the substrate side of the solar cell element into contact with the first electrode portion and the protruding second electrode portion, respectively.

According to the fourth aspect of the present invention, since all the probes are disposed on the substrate side, namely, on the side opposite to the light-receiving surface side of the element, there is no problem that the light irradiation conditions are disturbed in the measurement of the photoelectric conversion characteristics of the solar cell element, whereby the measurement accuracy can be improved.

For the purpose of solving the above-described problems, according to a fifth aspect of the present invention, there is provided an apparatus for measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the apparatus comprising:

means for fixing and holding the solar cell element with a light-receiving-side surface of the solar cell element having the photoelectric conversion layer being an upper surface;

a light source for irradiating the photoelectric conversion layer of the solar cell element with a light;

means for bringing a probe provided on the substrate side of the solar cell element into contact with the first electrode portion; and

means for bringing into contact with the second protruding electrode portion, a plate-shaped probe disposed and fixed with no clearance between a lower surface of the light shielding mask and the protruding second electrode portion.

According to the fifth aspect of the present invention, since the probe brought into contact with the second electrode portion on the light-receiving surface side is disposed below the lower surface of the light shielding mask without clearance, there is no problem that the light irradiation conditions are disturbed in the measurement of the photoelectric conversion characteristics of the solar cell element, whereby the measurement accuracy can be improved.

For the purpose of solving the above described problems, according to a sixth aspect of the present invention, there is provided an apparatus for measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the apparatus comprising:

a stage for placing and fixing the solar cell element thereon with a light-receiving surface of the solar cell element having the photoelectric conversion layer being the upper surface;

a driver for raising/lowering the stage;

a light shielding mask with an aperture disposed and fixed above the light-receiving surface;

probes provided on the substrate side of the solar cell element;

a driver for raising/lowering the probes;

means for pressing the solar cell element placed and fixed on the stage against a lower surface of the light shielding mask through raising of the stage and fixing the solar cell element, and then bringing the probes into contact with the first electrode portion and the protruding second electrode portion, respectively; and

means for irradiating the photoelectric conversion layer with a light through the aperture of the light shielding mask.

According to the sixth aspect of the present invention, since all the probes are arranged on the substrate side, namely, on the side opposite to the side of the light-receiving surface of the element, there is no problem that the light irradiation conditions are disturbed in the measurement of the photoelectric conversion characteristics of the solar cell element, whereby the measurement accuracy can be improved.

### BRIEF DESCRIPTION OF THE DRAWINGS

FIG. 1 is a conceptual sectional view illustrating the method and apparatus for measuring the photoelectric conversion characteristics of a solar cell element in accordance with a first embodiment of the present invention;

FIG. 2 is a plan view of a light-shielding mask involved in the first embodiment of the present invention;

FIG. 3 is a schematic sectional view (for a case where probes are not in contact with electrodes) of a relevant part of the apparatus for measuring the photoelectric conversion characteristics of the solar cell element, presented for the purpose of supplementing the description on the first embodiment of the present invention;

FIG. 4 is a schematic sectional view (for a case where probes are in contact with electrodes) of the relevant part of the apparatus for measuring the photoelectric conversion characteristics of the solar cell element, presented for the purpose of supplementing the description on the first embodiment of the present invention;

FIGS. 5A and 5B are schematic plan views of a stage involved in the first embodiment of the present invention;

FIGS. 6A and 6B are conceptual sectional views illustrating the method and apparatus for measuring the photoelectric conversion characteristics of a solar cell element in accordance with a second embodiment of the present invention;

FIG. 7 is a conceptual sectional view illustrating the method and apparatus for measuring the photoelectric conversion characteristics of a solar cell element in accordance with a third embodiment of the present invention;

FIG. 8 is a conceptual sectional view illustrating the method and apparatus for measuring the photoelectric conversion characteristics of a solar cell element in accordance with a fourth embodiment of the present invention;

FIGS. 9A and 9B are conceptual sectional views illustrating the method and apparatus for measuring the photoelectric conversion characteristics of a solar cell element in accordance with a fifth embodiment of the present invention;

FIG. 10 is a plan view of an example of a conventional solar cell element as viewed from the light-receiving surface side thereof, including a partial perspective view;

FIG. 11 is a schematic sectional view showing the structure of a conventional solar cell element; and

FIG. 12 is a schematic sectional view illustrating the manner of probe contact in conventional method and apparatus for measuring the photoelectric conversion characteristics of a solar cell element.

### DESCRIPTION OF THE PREFERRED EMBODIMENTS

Description will be made below on preferred embodiments of the present invention on the basis of the accompanying drawings, but the present invention is not limited by these embodiments.

### First Embodiment

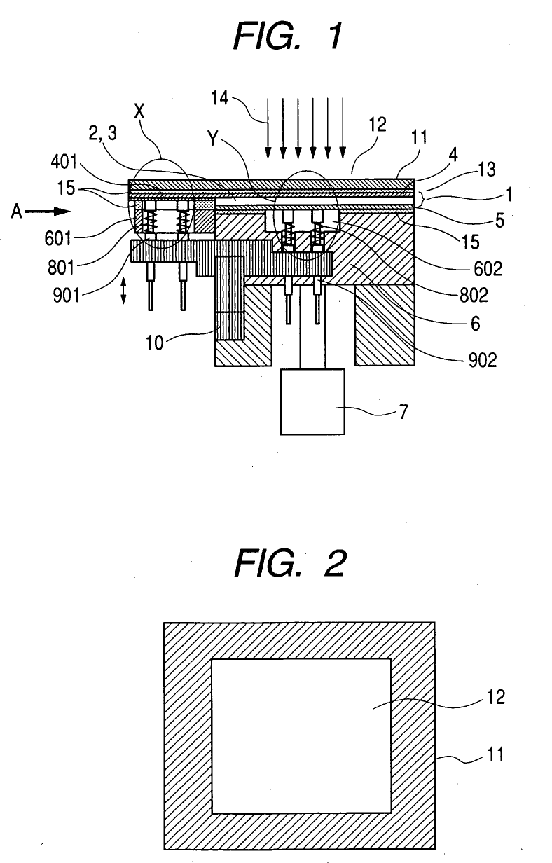

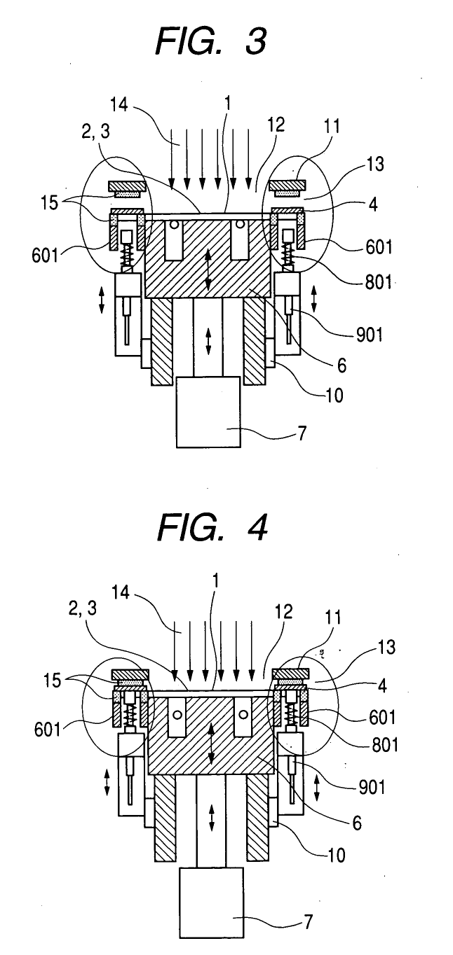

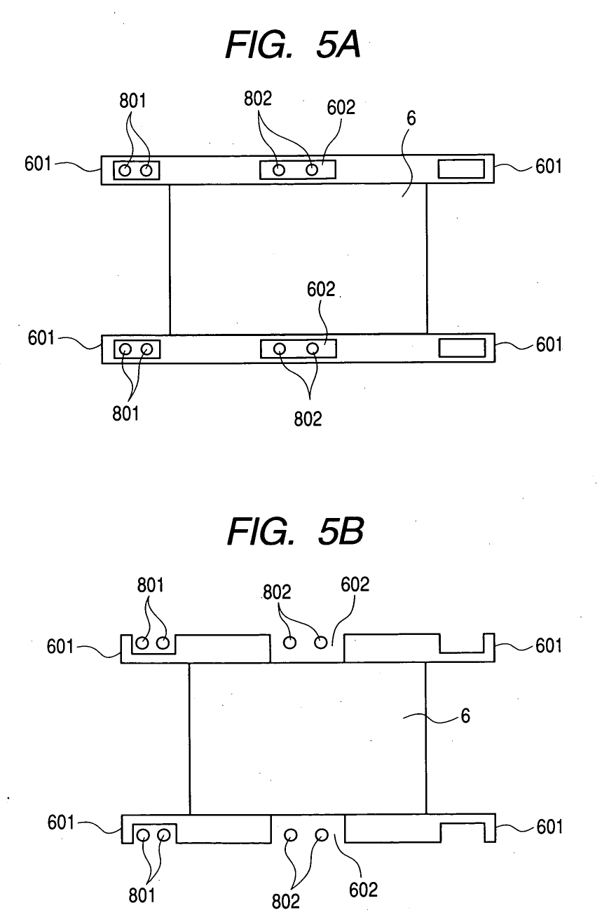

FIG. 1 is a conceptual sectional view illustrating the method and apparatus for measuring the photoelectric conversion characteristics of a solar cell element in accordance with a first embodiment of the present invention. FIG. 2 is a plan view of a light-shielding mask involved in the first embodiment of the present invention. FIGS. 3 and 4 are views as seen along the direction indicated by an arrow A in FIG. 1, presented for the purpose of supplementing the description on the first embodiment of the present invention, and the regions each surrounded with a circle in these figures are the sectional views corresponding to the X portions each surrounded with a circle in FIG. 1. Additionally, FIG. 3 is a view showing the state where the solar cell element is mounted on the stage and the probes are not in contact with the electrodes, while FIG. 4 is a view showing the state where the solar cell element is mounted on the stage and the probes are in contact with the electrodes. FIGS. 5A and 5B are schematic plan views of a stage involved in the first embodiment of the present invention.

Although the photoelectric conversion layer (a semiconductor layer) in an actual solar cell element is constituted of a plurality of layers, the plurality of layers are not directly relevant to the essential features of the present invention, and accordingly omitted in FIGS. 1, 2, 3, 4, 5A and 5B.

In FIGS. 1, 2, 3, 4, 5A and 5B, reference numeral 1 denotes a solar cell element; 2 denotes a light-receiving surface (a semiconductor layer) of the solar cell element 1; 3 denotes a substrate (conductive substrate) on which the light-receiving surface (semiconductor layer) 2 is formed; 4 denotes a second electrode provided on the light-receiving surface 2 side; 401 denotes an electrode portion which is a part of the second electrode 4 and protrudes from the substrate 3; 5 denotes a first electrode portion provided on the lower surface of the substrate 3; 6 denotes a stage on which the solar cell element 1 is placed; 601 denotes a protrusion of the stage 6 corresponding to the protruding electrode portion 401 of the second electrode 4; 602 denotes a cutout portion for the first electrode portion 5 to contact the probe; 7 denotes a driver for raising/lowering the stage 6; 801 and 802 denote probes to contact the protruding electrode portion 401 and the first electrode portion 5, respectively; 901 and 902 denote blocks for fixing the probes 801 and 802, respectively; 10 denotes a driver for raising/lowering the probes 801 and 802 and the probe fixing blocks 901 and 902; 11 denotes a light shielding mask; 12 denotes an aperture of the light shielding mask 11; 13 denotes a gap between the lower surface of the light shielding mask 11 and the upper surface of the second electrode 4; 14 denotes a light that irradiates the light-receiving surface 2 of the solar cell element 1; and 15 denotes insulating sheets provided on the lower surface of the light shielding mask 11 and on the upper surface of the protrusion 601 of the stage 6. Incidentally, the tip of the probe 801 to be brought into contact with the protruding second electrode portion 401 has a flat shape, while the tip of the probe 802 to be brought into contact with the first electrode portion 5 is provided with a plurality of protrusions.

In the present embodiment, a thin film amorphous silicon solar cell element 1 is placed on the stage 6 with the light-receiving surface 2 thereof being the upper surface, as shown in FIGS. 1 and 2, and the lower surface of the substrate 3 of the solar cell element 1 is brought into contact with the stage 6 and the solar cell element 1 is fixed in close contact to the stage 6 with the aid of a fixing means such as vacuum adhesion, as shown in FIG. 3. Then, by raising the stage 6 with the aid of the driver 7 for raising/lowering as shown in FIG. 4, the upper surface of the second electrode 4 of the solar cell element 1 is pressed against and fixed to the insulating sheet 15 disposed at the location corresponding to the position of the second electrode 4 on the lower surface of the light shielding mask 11. Furthermore, in this state, the probes 801 and 802 provided on the side opposite to the light-receiving surface 2 side of the solar cell element 1 are driven by means of the driver 10 for raising/lowering to bring the probes 801 and 802 into contact with the protruding electrode portion 401 of the second electrode 4 (see X portion surrounded with circle in FIG. 1) and the first electrode portion 5 (see Y portion surrounded with circle in FIG. 1) of the solar cell element 1 from below, respectively, then the whole region of the effective area of the light-receiving surface 2 is irradiated with a light through the aperture 12 of the light-shielding mask 11, and thus the photoelectric conversion characteristics are measured.

By adopting the above described configuration, even when conventional spring probes are used, since all the probes to be in contact with the electrodes arranged on both sides are not present on the light-receiving surface side, the probes and the driving system therefor do not block the irradiating light, and the irradiation conditions during the measurement of the photoelectric conversion characteristics are not disturbed, so that a high accuracy measurement of the photoelectric conversion characteristics can be carried out.

Incidentally, although as shown in the above described configuration, as the probes to be in contact with the first electrode portion and the protruding second electrode portion, probes are attached which themselves have a low internal resistance and each having a compression coil spring provided at the periphery thereof, as far as the measurement accuracy is not so critical, probes with a conventional structure having a compression coil spring provided inside thereof may also be used.

Additionally, in the above described configuration, since the stage 6 has a shape shown in FIGS. 5A and 5B, in a step prior to bringing the probes 801 and 802 into contact with the protruding second electrode portion 401 and the first electrode portion 5, those portions of the electrodes near the probe-contact portions are interposed to be fixed between the insulating sheet 15 adhered and fixed to the lower surface of the light shielding mask 11 and the stage 6. Therefore, even when the condition is such that warping of the solar cell element 1 or bending of the protruding electrode portion 401 of the second electrode 4 prevents the probes 801 or 802 from perpendicularly contacting the electrode portions, the contact condition is corrected such that the probes 801 and 802 can be made to perpendicularly contact the electrode portions, thereby ensuring stable contact condition. Accordingly, a high accuracy measurement of the photoelectric conversion characteristics is made possible.

Furthermore, use of an elastic silicone rubber sheet as the insulating sheet 15 in the above described configuration makes it possible to relieve the mechanical shock to the electrode portions of the solar cell element caused by the pressing operation against the light shielding mask through raising of the stage 6, and at the same time, the mechanical shock to the probes at the time of contact with the electrode portions can be relieved.

Incidentally, although in the present embodiment, the probe having the flat tip shape is provided for the protruding second electrode portion 401, while the probe having plural protrusions on the tip thereof is provided for the first electrode portion 5, appropriate modification of the tip shapes, in conformity with the surface conditions of the protruding second electrode portion 401 and the first electrode portion 5, makes it possible to attain more stable contact.

In the present embodiment, as shown in the above described configuration, since the probes to be in contact with the solar cell element are arranged on the same side, the probes 801 to be in contact with the protruding second electrode portion 401 and the probes 802 to be in contact with the first electrode portion 5 can be fixed to a common fixing block, so that the number of the constituent members for the probe raising/lowering driver can be reduced and thus the device can be simplified.

Additionally, in the present embodiment, the shape of the protrusion 601 of the stage 6 corresponding to the protruding electrode portion 401 of the second electrode 4 and the shape of the cutout portion 602 for the first electrode portion 5 to contact the probe are as shown in FIG. 5A wherein those portions at the periphery of the stage corresponding to the probes 801 and 802 are hollowed out. However, as far as stable contact state between the electrode 401 of the solar cell element and the, probe 801 can be secured and stable contact state between the first electrode portion 5 and the probe 802 can be secured, the cutout shapes as shown in FIG. 5B may also be adopted. In the case of the shapes shown in FIG. 5B, the visibility of the contact state between the probe 801 and the electrode 401 and the contact state between the probe 802 and the electrode 5 is improved, so that the maintenance of the probes can easily be carried out.

### Second Embodiment

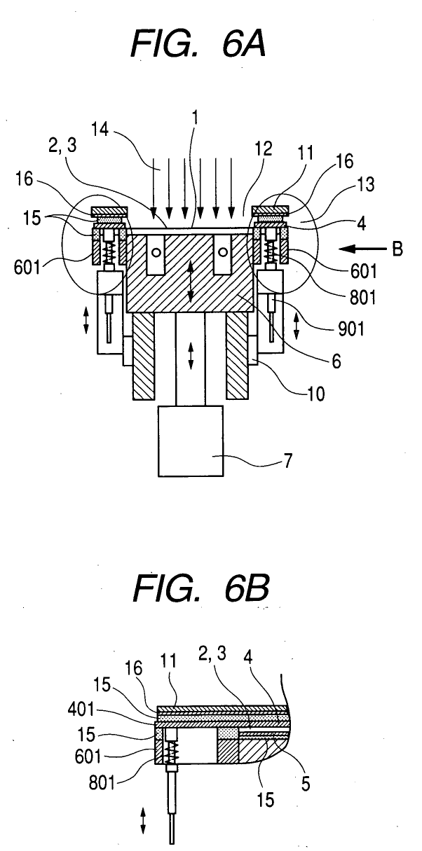

FIGS. 6A and 6B are conceptual sectional views illustrating the method and apparatus for measuring the photoelectric conversion characteristics of a solar cell element in accordance with a second embodiment of the present invention; FIG. 6A is a view corresponding to FIG. 4 in the first embodiment, and FIG. 6B is a schematic sectional view of the regions each surrounded with a circle in FIG. 6A as seen along the direction of an arrow B.

The present embodiment is different from the first embodiment of the present invention in that a holding structure 16 made of a metal plate with the same aperture as to the aperture of the light shielding mask 11 is provided, in addition to the light shielding mask 11, between the light shielding mask 11 and the stage 6, directly below the light shielding mask 11, and thus the second electrode 4 of the solar cell element 1 is fixed; and a sheet of a silicone rubber as the insulating sheet 15 is adhered to the lower surface of the holding structure 16.

By adopting the above described configuration, similarly to the first embodiment, even when conventional spring probes are used, since all the probes to be in contact with the electrodes arranged on the both sides are not present on the light-receiving surface side, the probes and the driver therefor do not block the irradiating light, and the irradiation conditions during the measurement of the photoelectric conversion characteristics are not disturbed, so that a high accuracy measurement of the photoelectric conversion characteristics can be carried out.

Additionally, since the holding structure 16 is newly arranged as a holder for the purpose of stabilizing the contact of the probes, as shown in the above-described configuration, the design constraining factors for the light-shielding mask can be reduced, thus raising the degree of freedom of design.

Incidentally, the shape of the holding structure 16 is not limited to the plate shape having an aperture, as far as the shape does not block the light irradiation to the light-receiving surface of the solar cell element, the contact stability of the probe is not affected, and the holding structure is electrically isolated from the light shielding mask. For example, the form of the holding structure may be such that holding structures each having a shape of a piece of a plate are partly disposed at regions in the vicinity of probe contact regions.

### Third Embodiment

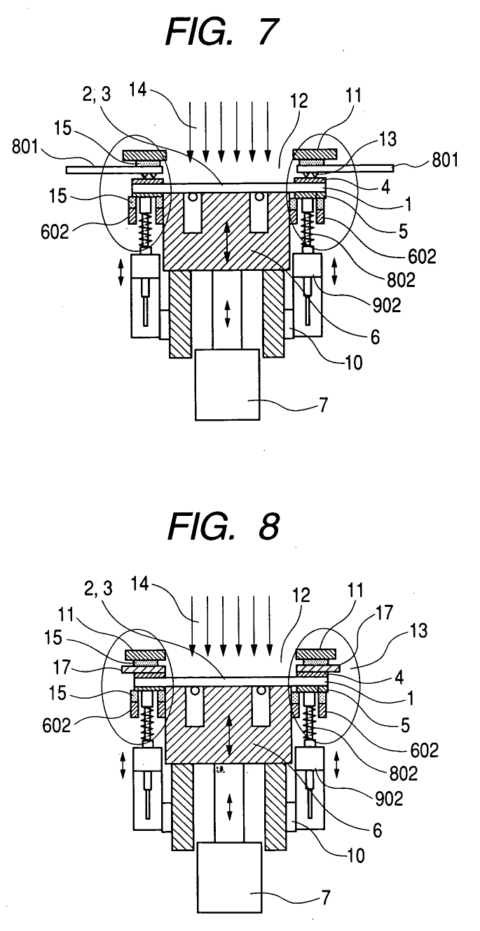

FIG. 7 is a conceptual sectional view illustrating the method and apparatus for measuring the photoelectric conversion characteristics of a solar cell element in accordance with a third embodiment of the present invention, corresponding to FIG. 4 in the first embodiment of the present invention. The regions each marked with a circle in FIG. 7 are the schematic sectional views of the portions corresponding to the region of the Y portion marked with a circle in FIG. 1.

The present embodiment is different from the first embodiment in that as shown in FIG. 7, the probe 801 made of a thin metal plate and provided with a protrusion is provided in the gap 13 between the lower surface of the light shielding mask 11 subjected to surface insulating treatment and the upper surface of the second electrode 4.

By adopting the above described configuration, since the probe 801 to be in contact with the second electrode 4 is disposed on the lower surface of the light shielding mask 11 without clearance, there is no problem such that the light irradiation conditions are disturbed during the measurement of the photoelectric conversion characteristics, so that the measurement accuracy can be improved.

Additionally, since it becomes possible to contact the second electrode 4 at locations other than the protruding second electrode portion 401, the degree of freedom of the electrode structure of the solar cell element to which the measurement is applicable is increased.

Incidentally, in the above-described configuration, since there are plural protrusions at the tip of the probe to be in contact with the protruding second electrode portion, stable contact is made possible, for example, even when the upper surface of the protruding second electrode portion is oxidized.

In the present embodiment, an insulating sheet is disposed on the lower surface of the light shielding mask, but a configuration in which a probe card having probe needles fixed to a printed circuit board may also be adopted.

### Fourth Embodiment

FIG. 8 is a conceptual sectional view illustrating the method and apparatus for measuring the photoelectric conversion characteristics of a solar cell element in accordance with a fourth embodiment of the present invention, corresponding to FIG. 4 in the first embodiment of the present invention. The regions in FIG. 8, each marked with a circle are the schematic sectional views of the portions corresponding to the region of the Y portion marked with a circle in FIG. 1.

The present embodiment is different from the first embodiment in that a conductive rubber sheet 17 is provided in the gap (space) 13 between the light shielding mask 11 and the second electrode 4 to be disposed on the lower surface of the light shielding mask 11, and the conductive rubber sheet 17 and the second electrode 4 are brought into contact with each other compressedly by raising the stage 6.

In the above described configuration, since the conductive rubber sheet 17 is disposed on the lower surface of the light shielding mask 11 without clearance and does not therefore block the irradiated light 14, the measurement is possible without disturbing the light irradiation conditions, so that the measurement accuracy of the photoelectric conversion characteristics of the solar cell element can be improved.

Additionally, since contact with the second electrode 4 is made possible at locations other than the protruding second electrode portion 401, the degree of freedom of the electrode structure of the solar cell element to which the measurement is applicable increases.

Furthermore, the adoption of a conductive rubber sheet as the probe makes it possible to relieve the mechanical shock to the electrode portions of the solar cell element caused by the pressing operation to the light shielding mask by the raising of the stage 6, and at the same time, makes it possible to conduct reliable contact with the electrode portions.

### Fifth Embodiment

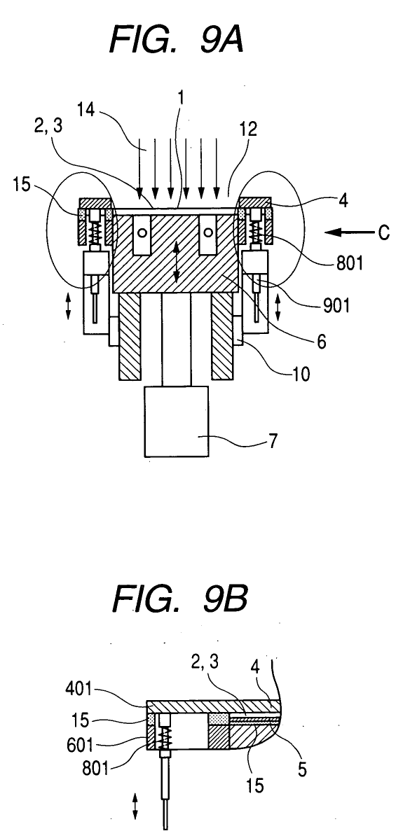

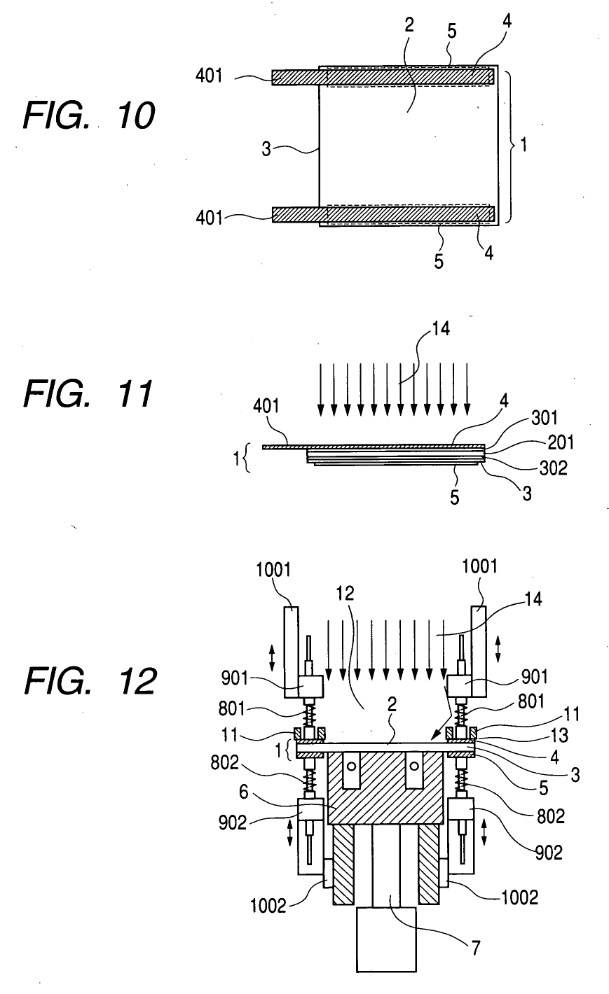

FIGS. 9A and 9B are conceptual sectional views illustrating the method and apparatus for measuring the photoelectric conversion characteristics of a solar cell element in accordance with a fifth embodiment of the present invention; FIG. 9A is a view corresponding to FIG. 4 in the first embodiment, and FIG. 9B is the schematic sectional view of the portions surrounded with a circle in FIG. 9A as viewed along the direction of an arrow C.

The present embodiment is different from the first embodiment in that the solar cell element 1 is a single-crystal silicon solar cell element, that the second electrode 4 is constituted of a rigid material, and that both the light shielding mask 11 and the insulating sheet 15 adhered to the lower surface of the light shielding mask employed in the first embodiment are omitted.

In the above described configuration, since the solar cell element 1 itself is rigid, and since the second electrode is formed of a rigid material, stable contact between the probes and the electrodes can be ensured even without a light-shielding mask, so that the measurement accuracy of the photoelectric conversion characteristics of the solar cell element can be improved.

While the present invention has been described and illustrated in connection with thin film amorphous silicon solar cells and single-crystal silicon solar cells, it will be appreciated by those skilled in the art that the present invention is not limited to those specific solar cells and is applicable to solar cell elements of other structures such as thin film polycrystal silicon solar cells or other photovoltaic elements as long as the same electrode structures as described above are adopted.

As described above, according to the measurement methods in accordance with the above-described first to third aspects of the present invention, the accuracy of measurement of the photoelectric conversion characteristics can be improved without disturbing the light irradiation conditions, so that measurement methods of high measurement accuracy can be provided.

Further, according to the measurement apparatuses in accordance with the above described fourth to sixth aspects of the present invention, the accuracy of measurement of the photoelectric conversion characteristics can be improved without disturbing the light irradiation conditions, so that measurement apparatuses of high measurement accuracy can be provided.

What is claimed is:

1. A method of measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light, the method comprising the steps of:
fixing the solar cell element with a light-receiving-side surface thereof having the photoelectric conversion layer being an upper surface; irradiating the photoelectric conversion layer of the solar cell element with a light from the upper surface side; and bringing probes provided on the substrate side of the solar cell element into contact with the first electrode portion and the protruding second electrode portion.

2. A method of measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the method comprising the steps of:
fixing the solar cell element with a light-receiving-side surface thereof having the photoelectric conversion layer being an upper surface; irradiating the photoelectric conversion layer of the solar cell element with a light from the upper surface side; bringing a probe provided on the substrate side of the solar cell element into contact with the first electrode portion; and bringing into contact with the second protruding electrode portion, a plate-shaped probe disposed and fixed with no clearance between the protruding second electrode portion and a lower surface of the light shielding mask.

3. A method of measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the method comprising the steps of:
irradiating the photoelectric conversion layer of the solar cell element with a light from the upper surface side; placing and fixing on a stage the solar cell element with a light-receiving-side surface thereof having the photoelectric conversion layer being the upper surface; pressing the solar cell element placed and fixed on the stage against the lower surface of the light shielding mask disposed and fixed on the side of the upper surface as the light-receiving surface of the solar cell element, through a raising/lowering movement of the stage, and then fixing the solar cell element; and bringing probes provided on the substrate side of the solar cell element into contact with the first electrode portion and the protruding second electrode portion, respectively.

4. An apparatus for measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light, the apparatus comprising:
means for fixing and holding the solar cell element with a light-receiving-side surface of the solar cell element having the photoelectric conversion layer being an upper surface;
a light source for irradiating the photoelectric conversion layer of the solar cell element with a light; and
a probe raising/lowering drive mechanism for bringing probes provided on the substrate side of the solar cell element into contact with the first electrode portion and the protruding second electrode portion, respectively.

5. An apparatus for measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the apparatus comprising:
means for fixing and holding the solar cell element with a light-receiving-side surface of the solar cell element having the photoelectric conversion layer being an upper surface;
a light source for irradiating the photoelectric conversion layer of the solar cell element with a light;
means for bringing a probe provided on the substrate side of the solar cell element into contact with the first electrode portion; and
means for bringing into contact with the second protruding electrode portion, a plate-shaped probe disposed and fixed with no clearance between a lower surface of the light shielding mask and the protruding second electrode portion.

6. An apparatus for measuring the photoelectric conversion characteristics of a solar cell element having a first electrode portion at least on a part of one surface of a substrate and having at least a photoelectric conversion layer and an upper electrode stacked in the mentioned order on the other surface of the substrate, a portion of an electrode electrically connected to the upper electrode protruding from the substrate to form a second electrode portion, in which the photoelectric conversion characteristics of the solar cell element are measured by bringing probes into contact with the first electrode portion and the protruding second electrode portion, respectively and irradiating the photoelectric conversion layer with a light through a light shielding mask having an aperture and disposed above the second electrode portion, the apparatus comprising:
a stage for placing and fixing the solar cell element thereon with a light-receiving surface of the solar cell element having the photoelectric conversion layer being the upper surface;
a driver for raising/lowering the stage;
a light shielding mask with an aperture disposed and fixed above the light-receiving surface;
probes provided on the substrate side of the solar cell element;
a driver for raising/lowering the probes;
means for pressing the solar cell element placed and fixed on the stage against a lower surface of the light shielding mask through raising of the stage and fixing the solar cell element, and then bringing the probes into contact with the first electrode portion and the protruding second electrode portion, respectively; and
means for irradiating the photoelectric conversion layer with a light through the aperture of the light-shielding mask.
